(19) United States
(12) Patent Application Publication
(10) Pub. No.: US 2023/0378976 A1
(43) Pub. Date: Nov. 23, 2023

(54) RECONSTRUCTION FEASIBILITY DETERMINATION METHOD, RECONSTRUCTION FEASIBILITY DETERMINATION APPARATUS AND PROGRAM

(71) Applicant: NIPPON TELEGRAPH AND TELEPHONE CORPORATION, Tokyo (JP)

(72) Inventors: Shin MIZUTANI, Tokyo (JP); Yasue KISHINO, Tokyo (JP); Takayuki SUYAMA, Tokyo (JP); Yoshinari SHIRAI, Tokyo (JP)

(21) Appl. No.: 18/247,160

(22) PCT Filed: Oct. 8, 2020
(86) PCT No.: PCT/JP2020/038169

§ 371 Date: Mar. 29, 2023

(51) Int. Cl. H03M 7/30; G06N 3/0455

(52) U.S. Cl. CPC H03M 7/6011; G06N 3/0455; H03M 7/6005

(57) ABSTRACT

The availability of decompression of compressed data can be determined when a computer executes a compression procedure for generating compressed data by compressing input data using an encoder of an auto-encoder which has completed learning, a decompression procedure for generating decompressed data by decompressing the compressed data using a decoder of the auto-encoder, a determination procedure for determining whether the input data has been learned by the auto-encoder based on a difference between the input data and the decompressed data, and a transmission procedure for transmitting the compressed data via a network if it is determined that the input data has been learned, and transmitting the input data via the network if it is determined that the input data has not been learned.

### TECHNICAL FIELD

The present invention relates to a decompression availability determination method, a decompression availability determination device, and a program.

### BACKGROUND ART

In recent years, sensor nodes used in a sensor network have come to operate with low power consumption and have not only functions of sensing and communication but also a function of processing information to a certain level, which makes it possible to have the functions of data compression, classification/identification of data, and detection of an event. This technical field is called edge computing (e.g., see NPL 1, etc.)

In addition, when observed sensing data obtained at a sensor node is transmitted to a center as it is, if the number of the sensor nodes increases, there is a possibility of the amount of communication to a center increasing to exceed the limit (bandwidth) of the allowable amount of communication. Thus, it is considered that the sensor data needs to be compressed at the sensor node to reduce the amount of information to be communicated to the center.

Since sensor data itself is not communicated in communication made after classification and identification of data and detection of an event, a kind of compression of an amount of communication is performed.

The following three points are considered as details of communication between the sensor node and the center.
(1) Sensor data is identified on the sensor node side, and only the identification result is sent to the center.
(2) The feature value of the sensor data is obtained on the sensor node side, and only the feature value is sent to the center.
(3) The sensor data is compressed on the sensor node side, and the compressed data is sent to the center.

Although the case of (1) functions when the sensor data is correctly identified, it is often desired to make the operation function well even if the sensor data is unsteady, and thus it is difficult to identify an unexpected input.

In the case of (2), although the sensor data is identified by using feature values thereof transmitted to the center, in a case of sensor data beyond expected identification, it is difficult to identify an unexpected input, unlike necessary feature values.

In the case of (3), a compression/decompression method depending on data can be used based on what kind of sensor data is to be compressed. In many cases, different compression/decompression methods are used depending on whether sensor data is an image, sound, or other time-series data. In addition, there are lossless compression and lossy compression, and generally the lossy compression has a higher compression rate than the lossy compression.

Here, in the case of (3), it is considered that an auto-encoder (AE) is used as a compressor/decompressor to transmit data compressed by the encoder of the sensor node to the center, and decompress the data using the decoder of the center. Although the AE can be used for any type of sensor data, it needs to be subject to learning of sensor data in advance (see NPL 2 and NPL 3). Since a compressor/decompressor is created through learning in the AE, only expected learning data and data close thereto can be decompressed, and the output of the AE will be different from the input data. With respect to such sensor data beyond expectation, the AE will not function as a compressor/decompressor.

Furthermore, in a situation in which edge computing is performed, the calculation capability and energy consumption of the sensor node side are generally limited, compared to those of the center side.

### CITATION LIST

### Non Patent Literature

[NPL 1] Mobile, Ubiquitous, and Intelligent Computing, [online], Internet <URL: https://rd.springer.com/content/pdf/10.1007%2F978-3-642-40675-1.pdf>
[NPL 2] Diederik P. Kingma, Max Welling, “Auto-Encoding Variational Bayes”, [online], Internet <URL: https://arxiv.org/abs/1312.6114>
[NPL 3] Carl Doersch, “Tutorial on Variational Autoencoders”, [online], Internet <URL: https://arxiv.org/abs/1606.05908>
[NPL 4] Kohei Komukai, Shin Mizutani, Yasue Kishino, Yutaka Yanagisawa, Yoshinari Shirai, Takayuki Suyama, Ren Ohmura, Hiroshi Sawada, Futoshi Naya “AutoEncoding Communication for Continual Classifier Updating in Distributed Recognition Sensor Networks”, Journal of the Information Processing Society of Japan, vol. 60, No. 10, pp. 1780-1795, (October 2019)
[NPL 5] Paul Bergmann, Sindy Loewe, Michael Fauser, David Sattlegger, Carsten Steger, “Improving Unsupervised Defect Segmentation by Applying Structural Similarity to Autoencoders”, arXiv: 1807.02011, Jul. 5, 2018.

### SUMMARY OF INVENTION

### Technical Problem

An auto-encoder is used as a compressor/decompressor sometimes when communication between a sensor node and a center is performed with compressed data and lossy compression is used on such a sensor network described above (NPL 4).

The auto-encoder includes an encoder portion and a decoder portion, compresses input data with the encoder, and decompress the compressed data with the decoder. The auto-encoder is a kind of a neural network, and is caused to perform learning such that input data to the encoder is output by the decoder as it is. Data used as learning data and data close thereto can be compressed and decompressed through learning and generalization. On the other hand, it is unclear whether the other data can be compressed/decompressed, and it is unclear whether input sensor data can be decompressed on the decoder side.

Although it is determined that the auto-encoder can decompress data when a distance of a difference between an input and an output (L2 norm) or the like is less than a certain threshold (NPL 5), input data is at the sensor node and output data is at the center on the above-described sensor network, and thus the input data or the output data need be transmitted to the center or the sensor node in order to compare the input data with the output data. Further, in general, input/output data of an auto-encoder is called an observation variable, and compressed data by an auto-encoder is called a latent variable.

In addition, since an auto-encoder can be expected to be generalized by learning, learning data itself can be naturally compressed and decompressed, and data close to the learning data can be compressed and decompressed likewise. Therefore, data obtained by the sensor node can cause the sensor network to function and operate as long as it is limited to learning data and data close thereto.

However, in actual observation, data corresponding to unlearned data may be obtained at the sensor node, and it is difficult to determine whether the input data can be decompressed only with the decompressed data on the center side. For this reason, it is necessary to determine whether transmitted data can be decompressed when the transmitted data is compressed.

The present invention has been contrived to solve the problems described above, and aims to make determination of decompression availability of compressed data.

### Solution to Problem

Thus, to solve the above-described problems, a computer executes a compression procedure for generating compressed data by compressing input data using an encoder of an auto-encoder which has completed learning, a decompression procedure for generating decompressed data by decompressing the compressed data using a decoder of the auto-encoder, a determination procedure for determining whether the input data has been learned by the auto-encoder based on a difference between the input data and the decompressed data, and a transmission procedure for transmitting the compressed data via a network if it is determined that the input data has been learned, and transmitting the input data via the network if it is determined that the input data has not been learned.

### Advantageous Effects of Invention

It is possible to make determination of decompression availability of compressed data.

### BRIEF DESCRIPTION OF DRAWINGS

FIG. 1 is a diagram illustrating a configuration example of a sensor network according to an embodiment of the present invention.

FIG. 2 is a diagram schematically illustrating a compressor and a decompressor according to an embodiment of the present invention.

FIG. 3 is a diagram for explaining an auto-encoder.

FIG. 4 is a diagram illustrating an example of an AE based on two-dimensional CNN used in image data.

FIG. 5 is a diagram illustrating an example of CNN-FC used in an auto-encoder.

FIG. 6 is a diagram for describing a learning data set used for the present embodiment.

FIG. 7 is a diagram for describing an unlearned data set used for the present embodiment.

FIG. 8 is a diagram illustrating an example of a hardware configuration of a center 10 according to an embodiment of the present invention.

FIG. 9 is a diagram illustrating an example of a functional configuration of a sensor network according to a first embodiment.

FIG. 10 is a flowchart for illustrating an example of the processing procedure for a communication process of sensor data according to the first embodiment.

FIG. 11 is a diagram illustrating an example of a functional configuration of a sensor network according to a second embodiment.

FIG. 12 is a flowchart for describing an example of the processing procedure for a communication process of sensor data according to the second embodiment.

FIG. 13 is a diagram showing histograms of input/output differences or latent variable differences.

FIG. 14 is a diagram showing histograms of input/output differences or latent variable differences when MSE is used for a loss function.

FIG. 15 is a diagram showing histograms of input/output difference or latent variable differences when BCE+0.0002×KLD is used in a loss function.

FIG. 16 is a diagram showing histograms of KLD between differences of the mean y of latent variables z or distributions of the latent variables z when BCE+0.0002×KLD is used in a loss function.

FIG. 17 is a diagram showing an entire image of a histogram of KLD between distributions of the latent variables z when BCE+0.0002×KLD is used in a loss function.

FIG. 18 is a diagram showing histograms of input/output differences or latent variable differences when MSE+0.0002×KLD is used in a loss function.

FIG. 19 is a diagram showing histograms of KLD between differences of the mean μ of latent variables z or distributions of the latent variables z when MSE+0.0002×KLD is used in a loss function.

FIG. 20 is a diagram showing an entire image of a histogram of KLD between distributions of the latent variables z when MSE+0.0002×KLD is used in a loss function.

FIG. 21 is a diagram showing thresholds and errors for each of NN structures of target AEs, input/output loss functions, and distance spaces.

FIG. 22 is a diagram showing evaluation results of compression/decompression by a plurality of types of AE.

### DESCRIPTION OF EMBODIMENTS

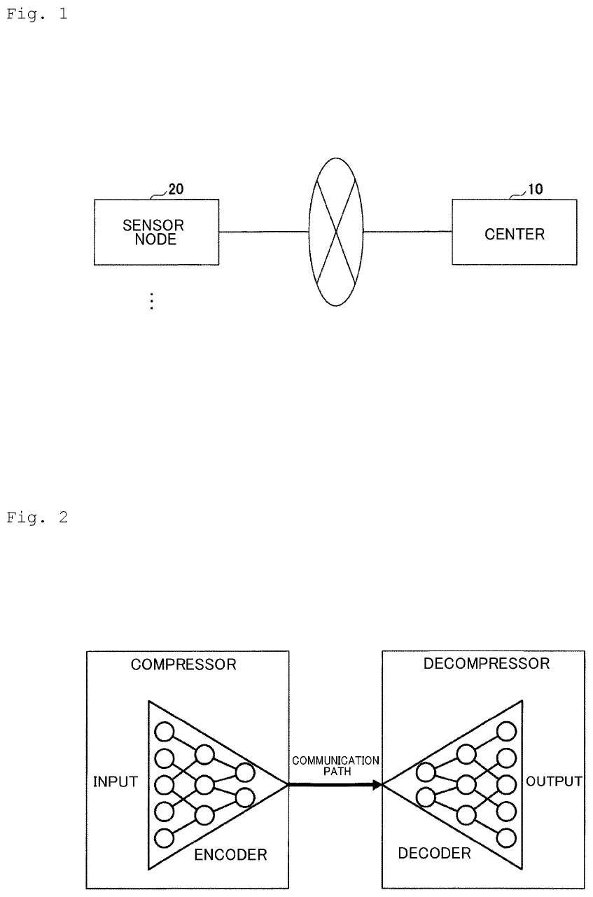

Hereinafter, embodiments of the present invention will be described with reference to the accompanying drawings. FIG. 1 is a diagram illustrating a configuration example of a sensor network according to an embodiment of the present invention. In the sensor network illustrated in FIG. 1, one or more sensor nodes 20 are connected to a center 10 via a network such as the Internet.

The sensor node 20 is a computer that is connected to a sensor (or has a sensor), compresses data including information sensed by the sensor (which will be referred to as “sensor data” below), and transmits the data that has been compressed (which will be referred to as “compressed data” below) to the center 10.

The center 10 is one or more computers having a function of receiving the compressed data transmitted from the sensor node 20 and decompressing the compressed data.

In the present embodiment, it is assumed that the sensor data is image data for the sake of convenience. Details of the image data will be described later. However, the data to which the present embodiment can be applied is not limited to data in a specific format.

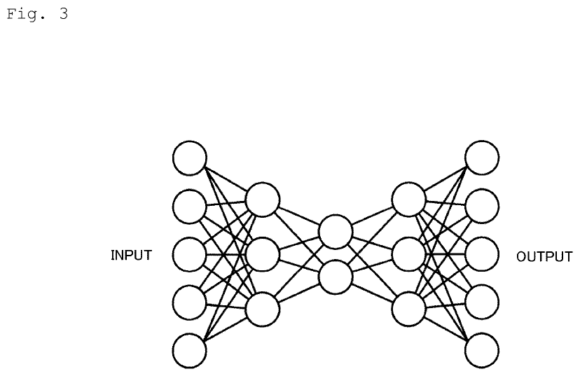

FIG. 2 is a diagram schematically illustrating a compressor and a decompressor according to an embodiment of the present invention. As illustrated in FIG. 2, the compressor is realized by an encoder of an auto-encoder (AE), the decompressor is realized by a decoder of the AE, and information with the minimum number of units in the intermediate layer of the AE is communicated as compressed data between the sensor node 20 and the center 10, thereby reducing an amount of communication.

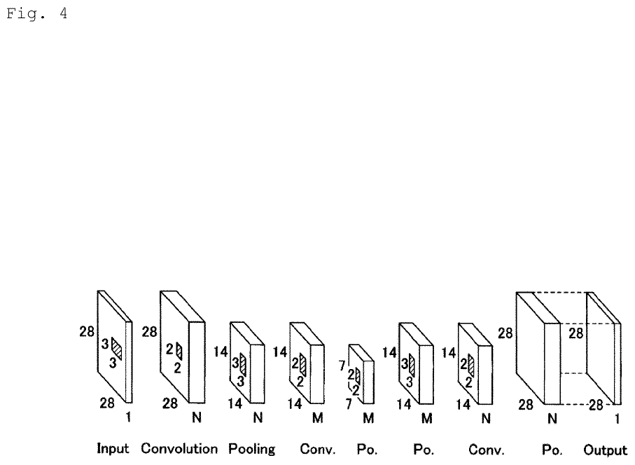

The AE is a kind of a layered neural network as illustrated in FIG. 3, and includes a compression coder (encoder) and a decompression decoder (decoder) (see NPL 2 and NPL 3). In FIG. 3, white circles represent units of the neural network, and lines connecting the units represent weights (links) between the units. In FIG. 3, the AE is depicted as having a five-layer structure in which the input is compressed from five dimension to two dimension and the input is reproduced on the output side.

In order for the encoder to compress the dimension of input data, the number of units is gradually decreased as the processing in each layer proceeds from left to right. In the output layer of the decoder, the number of units decreased in the intermediate layer increases to the same number of units as the input layer of the encoder, and the input information is decompressed.

That is, in an ordinary AE, an encoder and a decoder have a plurality of layers, and the intermediate layer at the center has the minimum number of units, forming an hourglass shape. The information of the unit with the minimum number of units is utilized as compressed data for communication between the sensor node 20 and the center 10, thereby reducing the communication amount. Further, the AE is subject to supervised learning so that input and output become the same. Although loss function used in learning varies depending on the data set used, it is Mean Square Error (MSE), Binary Cross Entropy (BCE), Categorical Cross Entropy (CCE), or the like.

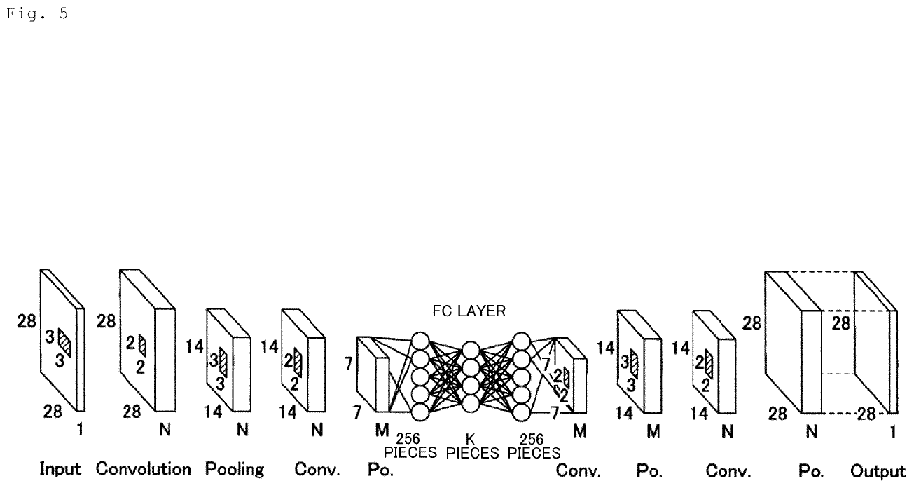

As described above, in the present embodiment, the sensor data is image data. The number of images of the image data is assumed to be 28×28, and each pixel is assumed to be 8 bits. Examples of the AE suitable for such image data include the AE as illustrated in FIG. 4.

The AE of 4 compresses and decompresses image data with an input of 8 bits from a matrix of 28×28, and thus normally, a convolutional neural network (CNN) is used (https://qiita.com/icoxfog417/items/5fd55fad152231d706c2). In the CNN, the dimension of information is reduced while maintaining the information of the spatial position, and the information is compressed into information such as features. The CNN shown in FIG. 4 has a 9-layer structure, and the input/output represents 28×28 dimensional vectors. The N and M of each intermediate layer represented by a rectangular parallelepiped represent the number of unit surfaces (types of filters), and the rectangle of the meshed portion represents the range of connection from the previous layer.

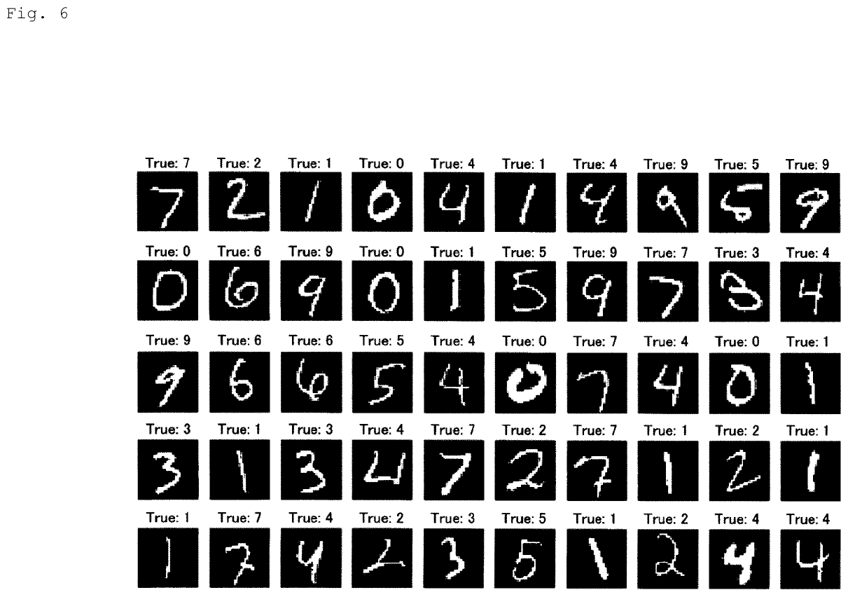

Furthermore, as shown in FIG. 5, a neural network having a structure in which all the connected layers (fully connected (FC) layers) are sandwiched by CNN is also suitable for image data.

In this embodiment, an example in which the AE shown in FIG. 4 or FIG. 5 is used as a compressor/decompressor will be described. Hereinafter, the AE is referred to as a “target AE”. The target AE is subject to learning in advance using sensor data observed by the sensor node 20 as input/output, and is set to be able to decompress the input as the output. In general, learning data for the target AE should have data sampled from the expected probability distribution of a certain event in the number of pieces sufficient to capture the features of the distribution. Data points other than sample points are considered to be interpolated with the generalization capability of the AE.

As the target AE, a variational auto-encoder (VAE) may be used, instead of a normal VE. In the VAE, in the space called a latent variable z corresponding to compressed data in the intermediate layer at the center, learning is generally performed such that data points have a Gaussian distribution N (0, I²). The encoder calculates the mean and the standard deviation of the Gaussian distribution from the input independently of each dimension of the latent variable, the latent variable z sampled with their probability distribution is used as an input of the decoder to perform learning so that the input for the encoder is reproduced. As a loss function of the VAE, a function created by adding Kullback-Leibler Divergence (KLD) representing a distance between distributions that makes a probability distribution become a set Gaussian distribution to a loss function between input/output (which will be referred to as an “input/output loss function” below) is used. This is the variational lower bound of a log-likelihood.

Although a neural network having a structure bilaterally symmetrical about the intermediate layer at the center is exemplified in the above example, any form of neural network may be employed as long as input and output have the same dimension (number of units), and any neural network can be used as a compressor/decompressor as long as input data can be decompressed in the output layer.

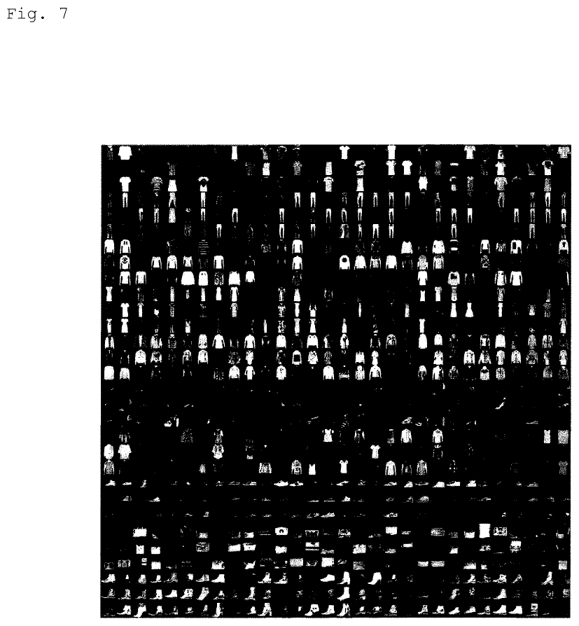

Next, a data set used for the present embodiment will be described. In the present embodiment, as learning data set of the target AE, handwritten numeric data (http://yann.lecun.com/exdb/mnist/), which is commonly used in the field of supervised machine learning of machine learning that is called MNIST as illustrated in FIG. 6 is used. This data is handwritten numeric data from 0 to 9 in which values from 0 to 255 (2⁸: 8 bit) are assigned to each of the 28×28 matrix and numbers 0 to 9 are given as the classification levels. The total number of pieces of data of MNIST is 60000, and is classified into 50000 pieces of data for normal learning and 10000 pieces of data for test. In the present embodiment, assuming that observation data obtained by a sensor node 2020 is 8-bit handwritten numeric data of a 28×28 matrix, a situation in which a center 1010 side desires the classification level is considered. That is, images obtained by a camera (the sensor node 2020) capturing handwritten numbers are input data, and output data from the center 1010 side is classification thereof.

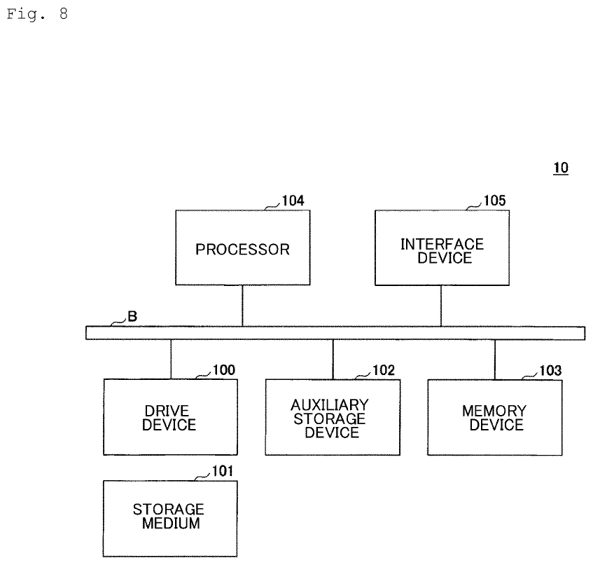

Next, as unlearned data which cannot be originally assumed, Fashion-MNIST (F-MNIST) (https://github.com/zalandoresearch/fashion-mnist) is used. As in MNIST, data of F-MNIST is monochrome image data of fashion items as illustrated in FIG. 7 in which values from 0 to 255 (2⁸: 8 bit) are assigned to each of the 28×28 matrix, and numbers 0 to 9 are given as the classification level. The total number of pieces of data of F-MNIST is 60000, and is classified into 50000 pieces of data for normal learning and 10000 pieces of data for test.

The data value to be input is used by normalizing the integer values 0 to 255 (2⁸: 8 bits) of the brightness of the pixels of the image to [0,1].

When the target AE is a VAE, the target AE performs learning such that the latent variable z is close to a probability density function N (0,I²), and thus it is considered that the learned data is close to the distribution, and unlearned data is separated from this distribution.

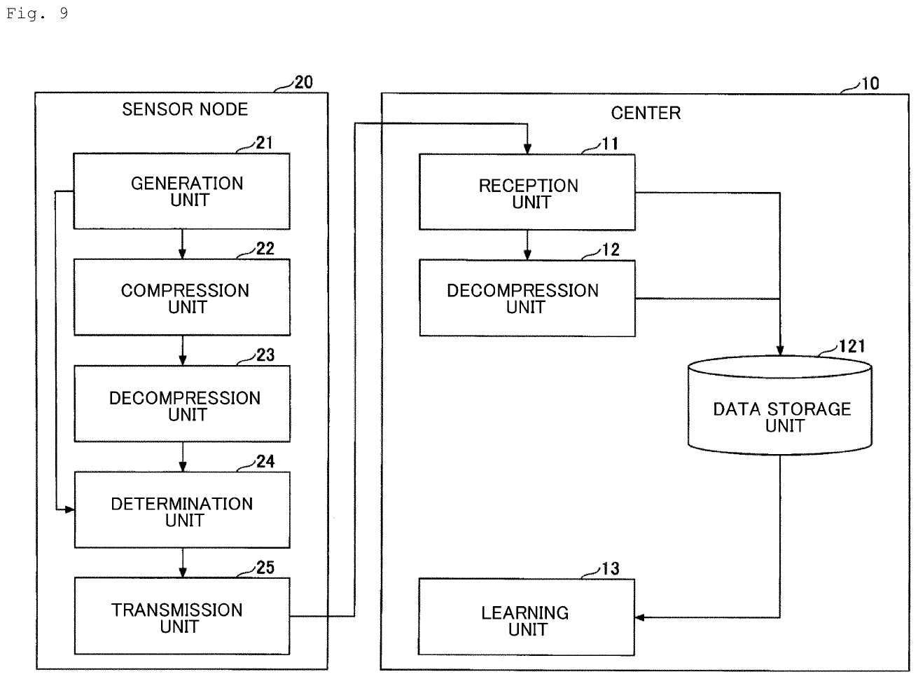

Next, a specific configuration example of a sensor network will be described. FIG. 8 is a diagram illustrating an example of a hardware configuration of the center 10 according to an embodiment of the present invention. The center 10 of FIG. 8 includes a drive device 100, an auxiliary storage device 102, a memory device 103, a processor 104, an interface device 105, and the like which are connected to each other through a bus B.

A program for realizing the processing performed by the center 10 is provided by a recording medium 101 such as a CD-ROM. When the recording medium 101 storing the program is set in the drive device 100, the program is installed from the recording medium 101 to the auxiliary storage device 102 via the drive device 100. However, the program may not necessarily be installed from the recording medium 101 and may be downloaded from another computer via a network. The auxiliary storage device 102 stores the installed program and stores necessary files, data, and the like.

The memory device 103 reads and stores the program from the auxiliary storage device 102 when there is an instruction to activate the program. The processor 104 is a CPU or a graphics processing unit (GPU), or a CPU and a GPU, and executes functions related to the center 10 in accordance with the program stored in the memory device 103. The interface device 105 is used as an interface for connection to a network.

The sensor node 20 may also have a hardware configuration similar to that of the center 10. However, the performance of the hardware of the sensor node 20 may be lower than that of the hardware of the center 10.

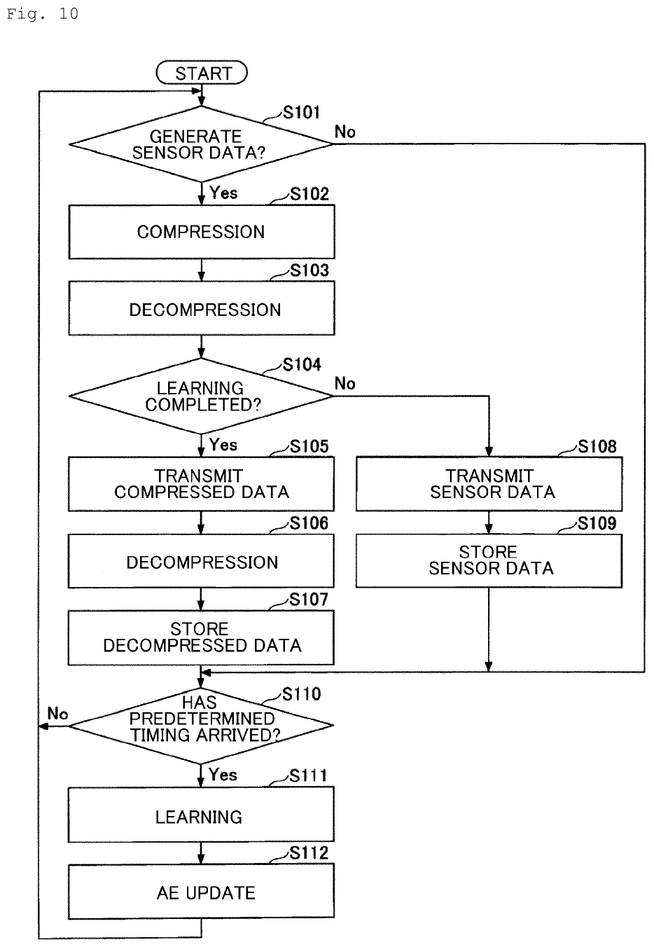

FIG. 9 is a diagram illustrating an example of a functional configuration of a sensor network according to a first embodiment. In FIG. 9, a sensor node 20 includes a generation unit 21, a compression unit 22, a decompression unit 23, a determination unit 24, and a transmission unit 25. These respective units are realized by the processor (e.g., CPU) of the sensor node 20 executing one or more programs installed in the sensor node 20.

The generation unit 21 generates sensor data including information sensed by a sensor.

The compression unit 22 functions as the compressor described above. That is, the compression unit 22 generates compressed data by compressing sensor data. In this embodiment, lossy compression is performed.

The decompression unit 23 generates decompressed data by decompressing the compressed data generated by the compression unit 22. The decompression unit 23 is realized by using the same decompressor as the decompressor (decoder) of the center 10. With the above operation, affinity with a target AE used as a compressor/decompressor for communication between the sensor node 20 and the center 10 is secured, and thus, the sensor node 20 has the entire target AE in the first embodiment.

The determination unit 24 determines availability of decompression of the compressed data generated by the compression unit 22 based on the difference between the sensor data generated by the generation unit 21 and the decompressed data generated by the decompression unit 23 (that is, observation variable data in an observation space which is a space in which the sensor data is observed). The determination of decompression availability refers to determining whether decompression is possible. In the determination of decompression availability, determination of whether the target AE has already learned or has not yet learned the compressed data (which will be referred to as “determination of learning completion” below) is realized. That is, if it is determined that the target AE has already learned the data, it is determined that the data can be decompressed, and if it is determined that the target AE has not yet learned the data, it is determined that the data cannot be decompressed.

In the present embodiment, the determination of learning completion is realized by using the anomaly detection technique (“https://scikit-learn.org/stable/auto_examples/plot_anomaly_comparison.html#sp hx-glr-auto-examples-plot-anomaly-comparison-py”, “Tsuyoshi Ite, Masashi Sugiyama “Anomaly Detection and Change Detection”, Kodansha”, and “Tsuyoshi Ite, “Introduction to Anomaly Detection using Machine Learning”, Corona Publishing Co., LTd.”). In the first embodiment, an anomaly detector based on an anomaly detection technique is arranged in the sensor node 20.

The anomaly detection technique is based on a probability distribution in which learning data is generated and a distance in a data space, and the Hotelling's theory in which a multi-variate error from learned data complies with a normal distribution (Tsuyoshi Ite, Masashi Sugiyama “Anomaly Detection and Change Detection”, pp 15-25, Kodansha), a method in which a local outlier factor (LOF) is introduced to the nearest neighbor algorithm (Tsuyoshi Ite, “Introduction to Anomaly Detection using Machine Learning”, pp 72-77, Corona Publishing Co., LTd.”, and Tsuyoshi Ite, Masashi Sugiyama “Anomaly Detection and Change Detection”, pp 41-51, Kodansha, etc.), threshold processing on a distance of input/output difference (L2 norm) of an AE (Paul Bergmann, Sindy Lowe, Michael Fauser, David Sattlegger, Carsten Steger, “Improving Unsupervised Defect Segmentation by Applying Structural Similarity to Autoencoders”, arXiv:1807.02011, 5 July, 2018), and the like can be used. In addition, from the viewpoint of classifying anomalies, a method of using One Class SVM (https://scikit-learn.org/stable/auto_examples/svm/plot_oneclass.html#sphx-glr-auto-examples-svm-plot-oneclass-py”, etc.), a method of using an ensemble of classifiers such as Isolation Forest (IF), or the like (“https://scikit-learn.org/stable/auto_examples/ensemble/plot_isolation_forest. html”, etc.), and the like can be used.

In the first embodiment, threshold processing for a distance of an input-output difference (L2 norm) of the AE in the anomaly detection technique will be described. That is, in the first embodiment, learning completion means a state in which a quantitatively determined distance (a degree of anomaly) of an input-output difference (a difference between sensor data and decompressed data) of the target AE is less than a predetermined threshold α. Unlearned means a state in which the distance is equal to or greater than the threshold α.

The transmission unit 25 transmits the compressed data to the center 10 when the determination unit 24 determines that the compressed data has been learned, and transmits the data (i.e., sensor data) before the compressed data to the center 10 when the determination unit 24 determines that the compressed data has not been learned.

Meanwhile, the center 10 has a reception unit 11, a decompression unit 12, and a learning unit 13. These respective units are realized by causing the processor 104 to execute one or more programs installed in the center 10. The center 10 also uses the data storage unit 121. The data storage unit 121 can be realized by using, for example, a storage device that can be connected to the auxiliary storage device 102 or the center 10 via a network, or the like.

The reception unit 11 receives compressed data or sensor data transmitted from the sensor node 20. When the sensor data is received, the sensor data is stored in the data storage unit 121.

The decompression unit 12 functions as the decompressor described above. That is, when compressed data is received by the reception unit 11, the decompression unit 12 decompresses the compressed data to generate decompressed data. The decompressed data is stored in the data storage unit 121.

The learning unit 13 performs additional learning or re-learning for the target AE by using a data group stored in the data storage unit 121. The compression unit 22 and the decompression unit 23 of the sensor node 20 and the decompression unit 12 of the center 10 are updated through the learning.

The data storage unit 121 stores decompressed data decompressed from the compressed data received from the sensor node 20 and sensor data received from the sensor node 20 (that is, sensor data determined that it has not been unlearned). Therefore, such data groups become learning data sets. In addition, data sets used for initial learning of the target AE may be stored in advance in the data storage unit 121. In this case, the data set may also be used in additional learning or re-learning.

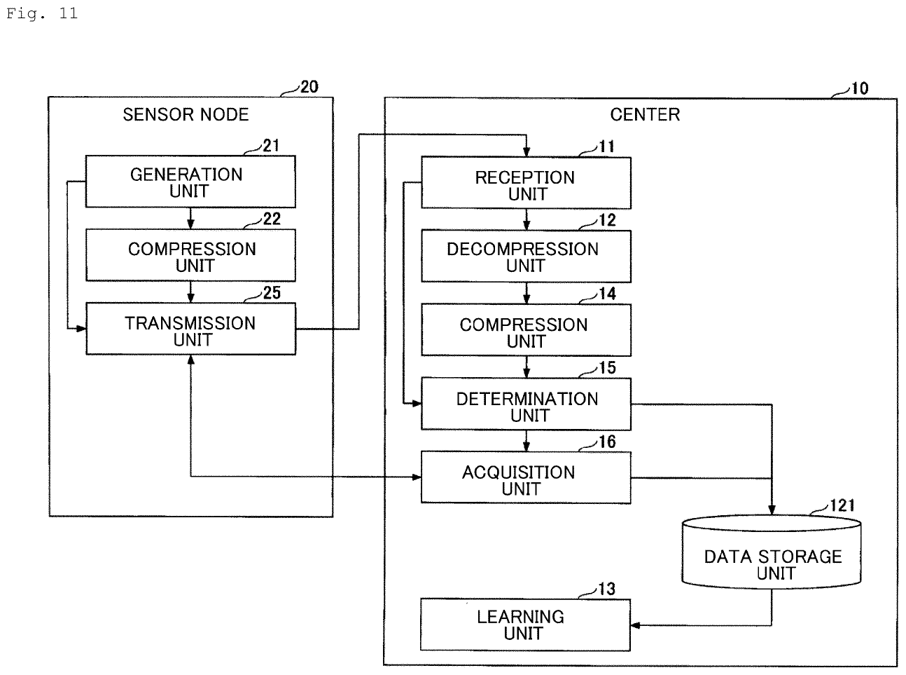

Hereinafter, a processing procedure for execution of the sensor node 20 and the center 10 of FIG. 9 will be described. FIG. 10 is a flowchart for describing an example of the processing procedure for a communication process of sensor data according to the first embodiment.

If the generation unit 21 of the sensor node 20 generates new sensor data (which will be referred to as “target sensor data” below) (Yes in S101), the compression unit 22 compresses the target sensor data by using the encoder of the target AE to generate compressed data (which will be referred to as “target compressed data” below) (S102). Then, the decompression unit 23 uses the decoder of the target AE to decompress the target compressed data to generate decompressed data (which will be referred to as “target decompressed data” below) (S103).

Subsequently, the determination unit 24 determines whether the target compressed data has been learned (determination of decompression availability) based on the difference between the target sensor data and the target decompressed data (S104). Specifically, the determination unit 24 calculates the distance between the difference between the target sensor data and the target decompressed data (input-output difference) (L2 norm), and compares the distance with a threshold α. The determination unit 24 determines that the target compressed data has been learned if the distance is less than the threshold α, and determines that the target compressed data has not been learned if the distance is equal to or more than the threshold α.

When it is determined that the target compressed data has been learned (Yes in S104), the transmission unit 25 transmits the target compressed data to the center 10 (S105). When the reception unit 11 of the center 10 receives the target compressed data, the decompression unit 12 decompresses the target compressed data to generate decompressed data (S106). Then, the decompression unit 12 stores the decompressed data in the data storage unit 121 (S107).

On the other hand, if it is determined that the target compressed data has not been learned (No in S104), the transmission unit 25 transmits the target sensor data to the center 10 (S108). When receiving the target sensor data, the reception unit 11 of the center 10 stores the target sensor data in the data storage unit 121 (S109).

In the center 10, the processing branches depending on whether the data received by the reception unit 11 is compressed data or sensor data, but the branch destination of such a branch may be determined based on identification information given to the header portion or the like of the data transmitted from the transmission unit 25 of the sensor node 20.

On the other hand, for example, if the number of pieces of data stored in the data storage unit 121 satisfies a predetermined condition, or at a predetermined timing such as an input of an instruction by a manager of the system (Yes in S110), the learning unit 13 uses a data set stored in the data storage unit 121 (a decompressed data set or a sensor data set related to unlearned), and a learned data set used for learning of the initial target AE to perform additional learning or re-learning of the target AE (S111). As a result, performance of the target AE as a compressor/decompressor can be improved. A known method may be used for learning of the target AE.

Then, the learning unit 13 executes processing for updating the target AE (S112). Specifically, the learning unit 13 updates the model parameter of the decoder as the decompression unit 12 to a value after additional learning or re-learning. In addition, the learning unit 13 transmits the model parameters of the encoder as the compression unit 22 and the decoder as the decompression unit 23 to the sensor node 20. The compression unit 22 and the decompression unit 23 of the sensor node 20 update the model parameters of the encoder or decoder with the received value.

By updating the model parameters of the target AE, the target AE can decompress unlearned data, and can decompress original learned data.

Next, a second embodiment will be described. In the second embodiment, different points from the first embodiment will be described. Points which are not mentioned particularly in the second embodiment may be similar to those of the first embodiment.

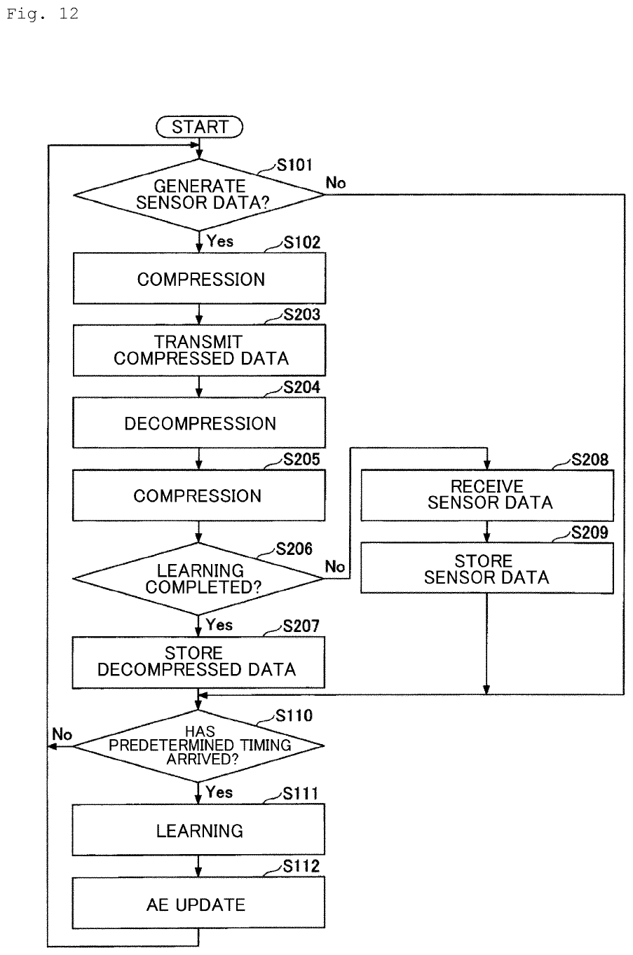

FIG. 11 is a diagram illustrating an example of a functional configuration of a sensor network according to the second embodiment. In FIG. 11 the same portions as or corresponding portions to those in FIG. 9 are assigned the same reference numerals, and a description thereof is omitted.

In FIG. 11, a sensor node 20 includes a generation unit 21, a compression unit 22, and a transmission unit 25. In the second embodiment, the transmission unit 25 basically transmits compressed data generated by the compression unit 22 to a center 10. However, when receiving a request for transmitting sensor data before compression from the center 10 after transmission of the compressed data, the transmission unit 25 transmits the sensor data to the center 10.

On the other hand, the center 10 further has, in addition to a reception unit 11, a decompression unit 12, and a learning unit 13, a compression unit 14, a determination unit 15, and an acquisition unit 16. The compression unit 14, the determination unit 15, and the acquisition unit 16 are realized by causing a processor 104 to execute one or more programs installed in the center 10.

The compression unit 14 generates compressed data by compressing the decompressed data generated by the decompression unit 12 by using an encoder of a target AE. Therefore, in the second embodiment, the center 10 has the entire target AE (the decompression unit 12 and the compression unit 14).

The determination unit 15 determines whether compressed data received by the reception unit 11 has been learned (determination of decompression availability) based on the difference between the compressed data received by the reception unit 11 and the compressed data generated by the compression unit 14 (that is, the difference between latent variable data in a latent space (which will be referred to as a “latent variable difference” below)). That is, the encoder of the target AE is arranged in the center 10 as the compression unit 14 considering affinity with the target AE used as a compressor/decompressor for communication between the sensor node 20 and the center 10. The determination unit 15 calculates a distance in the difference between a reproduced latent variable (an output expression obtained by most reducing the number of units of the target AE) obtained by inputting the decompressed data of sensor data to the encoder (the compression unit 14) and the latent variable itself (the compressed data received by the reception unit 11) transmitted from the sensor node 20 to the center 10. The determination unit 15 compares the distance with a predetermined threshold S, and determines learning completion of the compressed data received by the reception unit 11. If the determination unit 15 determines that the compressed data received by the reception unit 11 has been learned, the decompressed data generated by the decompression unit 12 is stored in the data storage unit 121.

If the determination unit 15 determines that the compressed data received by the reception unit 11 has not been learned, the acquisition unit 16 acquires the sensor data before compression of the compressed data from the sensor node 20, and stores the sensor data in the data storage unit 121.

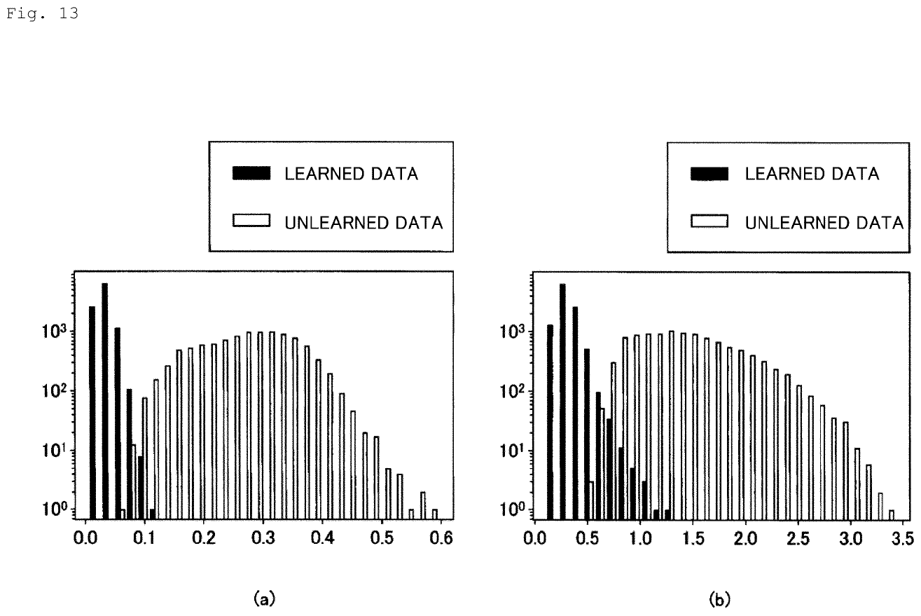

FIG. 12 is a flowchart for describing an example of the processing procedure for a communication process of sensor data according to the second embodiment. Steps of FIG. 12 that are the same as those of FIG. 10 are denoted by the same step numbers, and description thereof will be omitted.

Following step S102, the transmission unit 25 transmits the target compressed data generated by the compression unit 22 to the center 10 (S203).

When the reception unit 11 of the center 10 receives the target compressed data, the decompression unit 12 decompresses the target compressed data to generate decompressed data (which will be referred to as “target decompressed data” below) (S204). Then, the compression unit 14 compresses the target decompressed data by using the encoder of the target AE to generate compressed data (which will be referred to as “compressed/reproduced data” below) (S205). Then, the determination unit 15 determines whether the target compressed data has been learned (determination of decompression availability) based on the difference (latent variable difference) between the target compressed data (the compressed data received by the reception unit 11) and the compressed/reproduced data (S206). Specifically, the determination unit 15 calculates a latent variable difference between the target compressed data and the compressed/reproduced data, and compares the distance with a threshold β. The determination unit 15 determines that the target compressed data has been learned if the distance is less than the threshold β, and determines that the target compressed data has not been learned if the distance is equal to or more than the threshold β. As the latent variable difference, various types of divergence and distance between distributions such as an L2 norm, divergence between probability distributions (various divergence, e.g., Kullback-Leibler (KL) divergence (KLD), a divergence, generalized KL divergence, Bhattacharyya distance, and Hellinger distance can be used according to the application.

If it is determined that the target compressed data has been learned (Yes in Step S206), the determination unit 15 stores the target decompressed data in the data storage unit 121 (Step S207).

On the other hand, if it is determined that the target compressed data has not been learned (No in S206), the acquisition unit 16 acquires sensor data (target sensor data) before compression of the target compressed data from a node of the center 10 (S208). Specifically, the acquisition unit 16 transmits a request for transmitting the target sensor data to the transmission unit 25 of the sensor node 20. The transmission unit 25 transmits the target sensor data to the acquisition unit 16 in response to the request for transmission. Subsequently, the acquisition unit 16 stores the acquired target sensor data in the data storage unit 121 (S209).

The second embodiment (i.e., the determination of learning completion (determination of decompression availability) based on the latent variable difference) may be applied to data other than data communicated between the sensor node 20 and the center 10. For example, the second embodiment may be applied to a system in which no network is interposed between a compressor and a decompressor.

Next, a method of setting the threshold α for the input/output difference in the first embodiment and the threshold P for the latent variable difference in the second embodiment will be described. Specifically, with two methods which are the method of the first embodiment and the method of the second embodiment, the input/output difference and the latent variable difference that become a histogram for various AE and VAE to set a threshold for determination of learning completion by using MNIST data sets will be described.

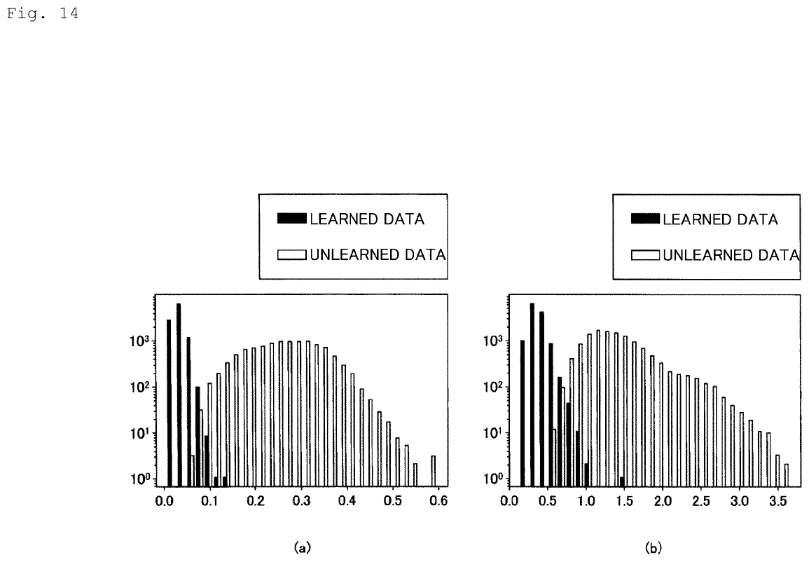

FIG. 13 are diagrams showing histograms of an input/output difference or a latent variable difference. In FIG. 13, (a) represents a histogram of the input/output differences calculated by the sensor node 20 of the first embodiment. The horizontal axis of the histogram of (a) represents the input/output difference, and the vertical axis thereof represents the value of Log₁₀ of a frequency (the number of pieces of data) corresponding to the input/output difference.

On the other hand, (b) represents a histogram of the differences of latent variables z (latent variable differences) calculated by the center 10 of the second embodiment. The horizontal axis of the histogram of (b) represents the latent variable difference, and the vertical axis thereof represents the value of Log₁₀ of a frequency (the number of pieces of data) corresponding to the latent variable differences.

Each of (a) and (b) of FIG. 13 uses, for determination of learning completion, a normal AE and BCE for a loss function, has the number of latent variable dimensions of 64, and is based on learned MNIST/unlearned F-MNIST data sets. The black bars represent a histogram based on learned data, and the white bars represent a histogram based on unlearned data.

In each of (a) and (b), the histogram of the learned data (painted in black) and the histogram of the unlearned data (painted in white) have distributions in the range of mutually different input/output differences or latent variable differences. Thus, it is considered that determination of learning completion can be performed and determination of decompression availability can be performed by setting a threshold (the threshold α or the threshold β) appropriate for the value of an input/output difference or a latent variable difference. In order to minimize an error recognition rate of the learned data and the unlearned data, the values of the input/output difference or the latent variable difference at the intersections of the histograms may be set as the threshold α or the threshold β.

In addition, although MNIST is selected as a learned data set and FMNIST is selected as an unlearned data set here, it is considered that, in general, the learning data set is given to become a learned data set, and the unlearned data set is unknown. When only the learned data set is known, a threshold corresponding to the error recognition rate of the learned data can be determined for the edge (tail) of the histogram (painted in black) based on the learned data. For example, if the error recognition rate is set to 0, a threshold may be set to be less than the input/output difference or the latent variable difference in which the (black) histogram are present.

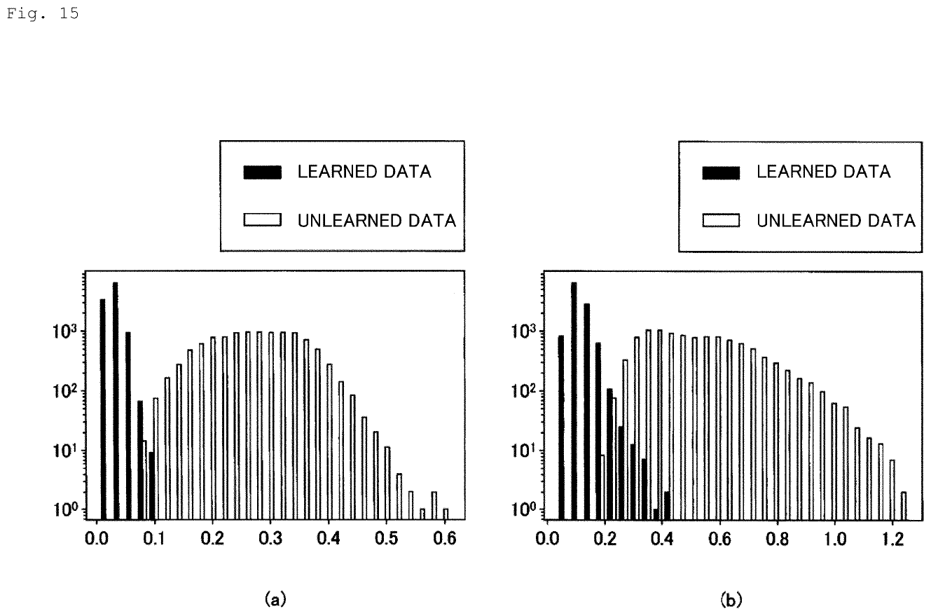

For comparison, FIG. 14 shows histograms in the case of an AE under the same conditions as those in FIG. 13 except that an MSE was used as a loss function. In FIG. 14, (a) represents a histogram of input/output differences, and (b) represents a histogram of differences of a latent variable z (latent variable differences).

The histograms of FIG. 14 are similar to those of FIG. 13, and it is considered that determination of learning completion can be made through the threshold processing.

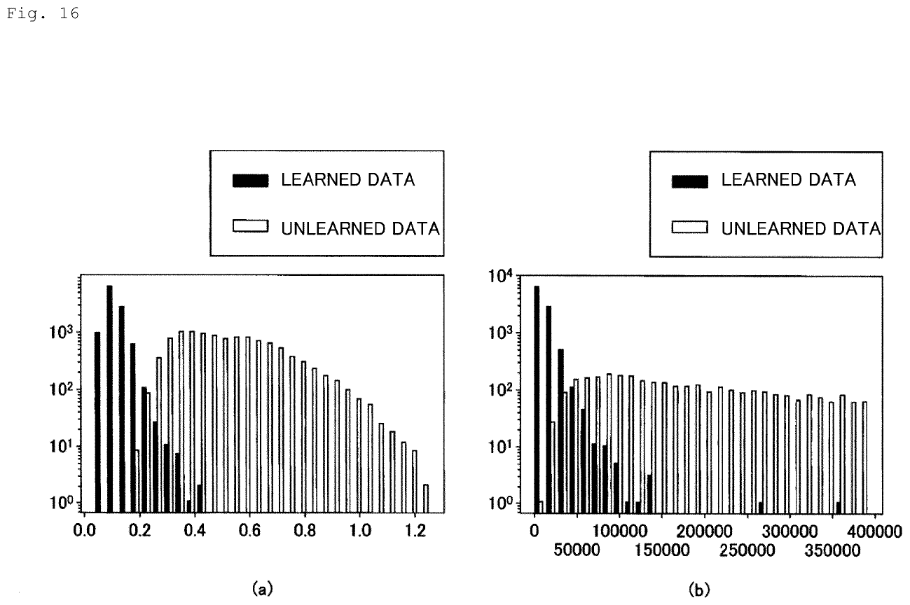

In addition, FIG. 15 shows histograms in the case in which a VAE is selected as a target AE, a BCE is selected as an input/output loss function, and the loss function is BCE+0.0002×KLD. In FIG. 15, (a) represents a histogram of input/output differences, and (b) represents a histogram of difference of a latent variable z (latent variable differences).

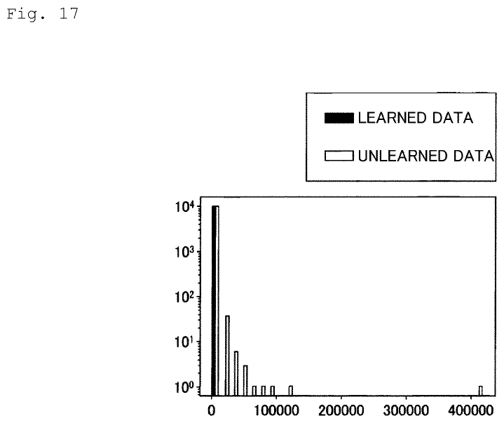

Furthermore, FIG. 16 shows a histogram of differences between the mean μ of the latent variable z and a histogram of KLD between the distributions of the latent variable z under the same conditions as those in FIG. 15. In FIG. 16, (a) represents a histogram of differences of the mean μ of the latent variable z, and (b) represents a histogram of the KLD between the distributions of the latent variable z. Since the latent variable z is sampled from the Gaussian distribution N (μ, σ²) based on the output μ of the encoder and log var (log variance), the difference between the latent variable distribution N (μ, σ²) and decompressed latent variable distribution N (μ\hat{ }, σ\hat{ }²) is expressed with KLD.

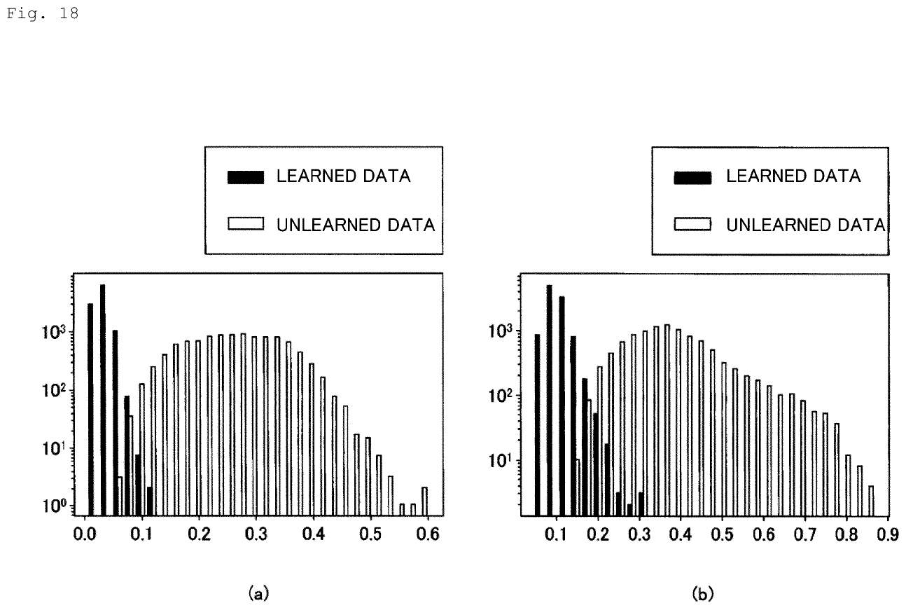

FIG. 17 is a diagram showing the entire image of the histogram of FIG. 16(b).

According to FIGS. 15 to 17, in the case in which a VAE is selected as a target AE, a BCE is selected as an input/output loss function, and the loss function is defined as BCE+KLD, determination of learning completion is considered to be made through threshold processing for histograms with the observation space x, the latent space z, the mean μ in the latent space, and the inter-distribution distance KLD.

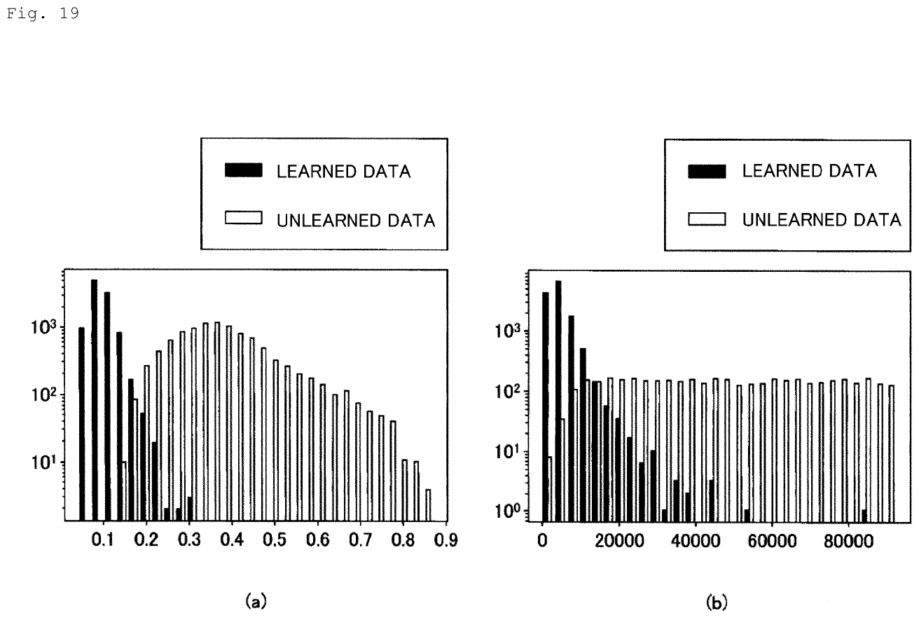

In addition, similarly, FIGS. 18 to 20 show histograms in a case in which a VAE is selected as a target AE, an MSE is selected as an input/output loss function, and the loss function is selected as MSE+0.0002×KLD.

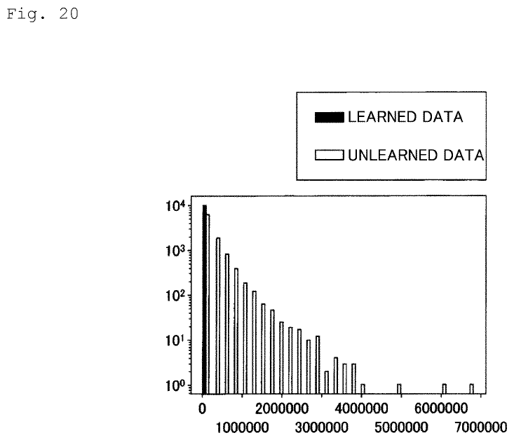

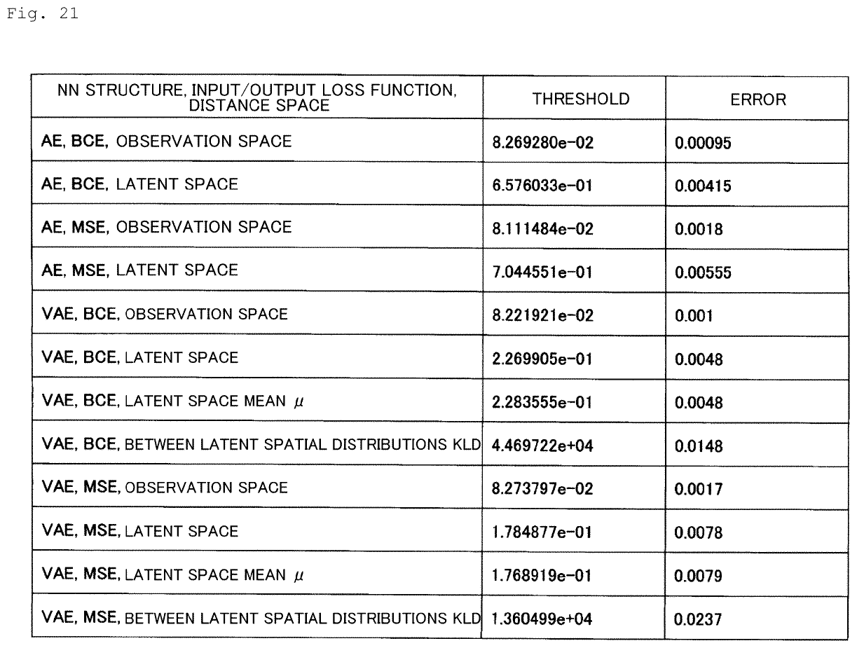

In other words, FIG. 18(a) shows a histogram of input/output differences, and FIG. 18(b) shows a histogram of differences of the latent variable z. FIG. 19(a) shows a histogram of differences between the mean μ of the latent variable z, and FIG. 19(b) shows a histogram of KLD between distributions of the latent variable z. FIG. 20 shows the entire image of the histogram of FIG. 19(b).

According to FIGS. 18 to 20, even in the case in which an MSE is selected as an input/output loss function, determination of learning completion is considered to be made through threshold processing for histograms with the observation space x, the latent space z, the mean μ in the latent space, and the inter-distribution distance KLD.

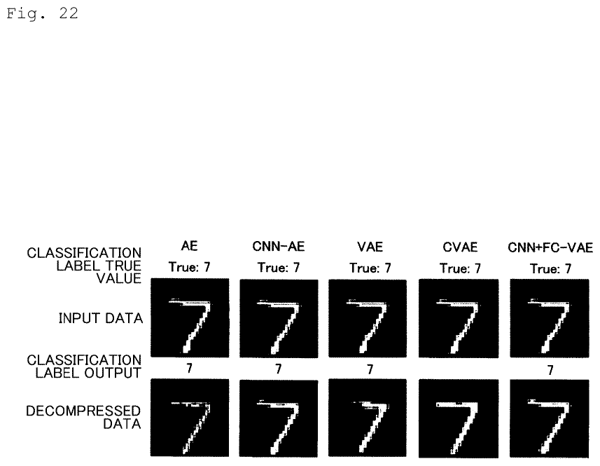

FIG. 21 shows thresholds and errors (L2 norm and KLD) of each of a neural network (NN) structure of the target AE (normal AE/VAE), the input/output loss functions (BCE/MSE), and the distance spaces (observation space/latent space).

In FIG. 21, the distances between data (data of the observation space or data of the latent space) are arranged in descending order, the thresholds are changed from a smaller value to a larger value, and the minimum error values are set as the thresholds. Thus, the thresholds are left-adjusted values.

According to FIG. 21, it is ascertained that, although errors are large in the case of the VAE, BCE, and latent space, determination of learning completion can be performed through the threshold processing with a certain degree of errors in other aspects.

Although the target AE has been described as a normal AE or a VAE having the structure shown in FIG. 4 or FIG. 5 in the above embodiments, the structure of the target AE is not limited to that shown in FIG. 4 or FIG. 5. For the ground of this, evaluation results by the present inventors for a compressor/decompressor using a plurality of kinds of AE will be introduced.

FIG. 22 is a diagram showing evaluation results of compression/decompression by a plurality of types of AE. In FIG. 22, input data, true values of classification labels of the input data, decompressed data, and classification label outputs are shown for five types of AE such as AE, CNN-AE, VAE, CVAE, CNN+FC−VAE. In addition, the AE indicates a fully connected AE, the CNN-AE indicates an AE with a CNN structure, the VAE indicates a fully connected VAE, the CVAE indicates a full connected conditional VAE, and the CNN+FC−VAE indicates a VAE with a combination of a CNN structure and full connection.

As is apparent from FIG. 22, compression/decompression was appropriately performed to an extent that classification was possible in any AE. For the CVAE which is a conditional VAE, the value of the classification label output is not required, and thus, it is not shown in the drawing.

Thus, an AE applicable to each of the above embodiments is not limited to a specific VAE.

According to each of the above-described embodiments, whether compressed data can be decompressed is determined as described above.

Further, by making determination of learning completion (determination of decompression availability), collecting unlearned data determined to have been unlearned (not possible to decompress), using the unlearned data, and performing additional learning or re-learning of the compressor/decompressor, the compressor/decompressor can handle the unlearned data.

Each of the above-described embodiments may be applied to various types of data and data to be compressed other than data to be transmitted from the sensor node 20 to the center 10.

In addition, although an example in which the center 10 executes the additional learning or re-learning of the target AE has been described in each of the above-described embodiments, this example is not based on principle constraints since it is rational to perform the operation on the side with affluent calculation resources and energy. Thus, the additional learning or re-learning of the target AE may be performed in principle at the node of the center 10. In particular, in the first embodiment, the node of the center 10 may execute additional learning or re-learning of the target AE based on data to be transmitted by the transmission unit 25 (compressed data or decompressed data) and original learned data.

In each of the above-described embodiments, the sensor node 20 and the center 10 are an example of a decompression availability determination device.

Although embodiments of the present invention have been described in detail above, the present invention is not limited to the specific embodiments described above, and various modifications and changes can be made within the scope of the gist of the present invention described in the claims.

### REFERENCE SIGNS LIST

10 Center
11 Reception unit
12 Decompression unit
13 Learning unit
14 Compression unit
15 Determination unit
16 Acquisition unit
20 Sensor node
21 Generation unit
22 Compression unit
23 Decompression unit
24 Determination unit
25 Transmission unit
100 Drive device
101 Recording medium
102 Auxiliary storage device
103 Memory device
104 Processor
105 Interface device
121 Data storage unit
B Bus

1. A decompression availability determination method executed by a computer, the method comprising:
generating compressed data by compressing input data using an encoder of an auto-encoder which has completed learning;
generating decompressed data by decompressing the compressed data using a decoder of the auto-encoder;
determining whether the input data has been learned by the auto-encoder based on a difference between the input data and the decompressed data; and
transmitting the compressed data via a network if it is determined that the input data has been learned, and transmitting the input data via the network if it is determined that the input data has not been learned.

2. The decompression availability determination method according to claim 1, further comprising:
causing the auto-encoder to perform learning using the data transmitted at the transmitting.

3. A decompression availability determination method executed by a computer, the method comprising:
generating decompressed data by decompressing first compressed data generated by compressing input data using an encoder of an auto-encoder that has completed learning, by using a decoder of the auto-encoder;
generating second compressed data from the decompressed data by using an encoder of the auto-encoder; and
determining whether the input data has been learned by the auto-encoder based on a difference between the first compressed data and the second compressed data.

4. The decompression availability determination method according to claim 3, further comprising:
acquiring the input data via a network when it is determined that the input data has not been learned; and
causing the auto-encoder to perform learning using the decompressed data of the input data determined to have been learned and the input data acquired at the acquiring.

5. The decompression availability determination method according to claim 3, further comprising:
receiving the first compressed data generated by compressing the input data using the encoder of the auto-encoder that has completed learning via a network.

6. A decompression availability determination device comprising:
a processor; and
a memory that includes instructions, which when executed, cause the processor to execute:
generating compressed data by compressing input data using an encoder of an auto-encoder which has completed learning;
generating decompressed data by decompressing the compressed data using a decoder of the auto-encoder;
determining whether the input data has been learned by the auto-encoder based on a difference between the input data and the decompressed data; and
transmitting the compressed data via a network if it is determined that the input data has been learned, and transmit the input data via the network if it is determined that the input data has not been learned.

7. (canceled)

8. A non-transitory computer-readable recording medium storing a program that causes a computer to execute the decompression availability determination method according to claim 1.
